(19) United States
(12) Patent Application Publication
(10) Pub. No.: US 2024/0217530 A1
(43) Pub. Date: Jul. 4, 2024

(54) IDENTIFICATION OF AN OBJECT IN ROAD DATA CORRESPONDING TO A SIMULATED REPRESENTATION USING MACHINE LEARNING

(71) Applicant: GM Cruise Holdings LLC, San Francisco, CA (US)

(72) Inventor: Ignacio Martin Bragado, Mountain View, CA (US)

(21) Appl. No.: 18/092,433

(22) Filed: Jan. 2, 2023

(51) Int. Cl. B60W 50/06; B60W 50/02; B60W 60/00

(52) U.S. Cl. CPC B60W 50/06; B60W 50/0205; B60W 60/001; B60W 2420/42; B60W 2420/52; B60W 2554/4026; B60W 2554/4029; B60W 2554/404

(57) ABSTRACT

Systems and techniques are provided for identifying an object in road data corresponding to a simulated representation in simulation data using machine learning. An example method includes receiving simulation data descriptive of one or more assets, wherein the one or more assets are synthetic representations of an object in a simulation scene. The example method further includes receiving sensor data collected by one or more sensors of an autonomous vehicle (AV) while navigating in a real-world environment, identifying an object in the sensor data using a machine learning model, the object corresponding to an asset of the one or more assets in the simulation data, determining a difference between the asset in the simulation data and the object in the sensor data, and based on the difference, determining whether to modify at least one of the asset in the simulation scene and one or more synthetic sensors.

### TECHNICAL FIELD

The present disclosure generally relates to identifying an object in road data corresponding to a simulated representation in simulation data using machine learning. For example, aspects of the present disclosure relate to techniques and systems for identifying an object in road data that corresponds to a simulated object in simulation data where the road data is collected by an autonomous vehicle in a real-world environment.

### BACKGROUND

An autonomous vehicle is a motorized vehicle that can navigate without a human driver. An exemplary autonomous vehicle can include various sensors, such as a camera sensor, a light detection and ranging (LiDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at fixed locations on the autonomous vehicles.

### BRIEF DESCRIPTION OF THE DRAWINGS

Illustrative examples and aspects of the present application are described in detail below with reference to the following figures:

FIG. 1 is a diagram illustrating an example system environment that can be used to facilitate autonomous vehicle (AV) navigation and routing operations, in accordance with some examples of the present disclosure;

FIG. 2A illustrates an example asset in a simulation scene for testing an AV, in accordance with some examples of the present disclosure;

FIG. 2B illustrates an example object captured in road data that is collected by AV sensor(s) in a real-world environment, in accordance with some examples of the present disclosure;

FIG. 3A illustrates an example LiDAR intensity image based on LiDAR data collected by synthetic sensor(s) of a simulated AV in simulation, in accordance with some examples of the present disclosure;

FIG. 3B illustrates an example LiDAR intensity image based on LiDAR data collected by AV sensor(s) in a real-world environment, in accordance with some examples of the present disclosure;

FIG. 4 is a flowchart illustrating an example process for identifying an object in road data corresponding to a simulated representation in simulation data using machine learning, in accordance with some examples of the present disclosure.

FIG. 5 illustrates an example of a deep learning neural network that can be used to identify an object in sensor data that corresponds to a simulated object in simulation data, according to some aspects of the disclosed technology; and

FIG. 6 is a diagram illustrating an example system architecture for implementing certain aspects described herein.

### DETAILED DESCRIPTION

Certain aspects and examples of this disclosure are provided below. Some of these aspects and examples may be applied independently and some of them may be applied in combination as would be apparent to those of skill in the art. In the following description, for the purposes of explanation, specific details are set forth in order to provide a thorough understanding of the subject matter of the application. However, it will be apparent that various aspects and examples of the disclosure may be practiced without these specific details. The figures and description are not intended to be restrictive.

The ensuing description provides examples and aspects of the disclosure, and is not intended to limit the scope, applicability, or configuration of the disclosure. Rather, the ensuing description of the examples and aspects of the disclosure will provide those skilled in the art with an enabling description for implementing an example implementation of the disclosure. It should be understood that various changes may be made in the function and arrangement of elements without departing from the scope of the application as set forth in the appended claims.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

As previously explained, autonomous vehicles (AVs) can include various sensors, such as a camera sensor, a light detection and ranging (LIDAR) sensor, a radio detection and ranging (RADAR) sensor, an audio sensor, amongst others, which the AVs can use to collect data and measurements that the AVs can use for operations such as navigation. The sensors can provide the data and measurements to an internal computing system of the AV, which can use the data and measurements to control a mechanical system of the AV, such as a vehicle propulsion system, a braking system, or a steering system.

Generally, AVs need to be tested in various simulations to determine safety metrics and determine any technology gaps or potential issues that may need to be addressed for the optimal functioning of the AV in a real-world environment. As follows, realistic simulation of various driving scenarios and realistic visual effects (e.g., realistic scenic representations or realistic scene features and/or objects) is generally important so that an AV can be tested in a simulated scene that emulates the real-world environment. In other words, a simulated scene/environment (e.g., a synthetic scene/environment) can contain simulated/synthetic scene features and/or objects that accurately model their corresponding real-world features and/or objects.

A manual process of pairing a real-world scene feature and/or object with a simulated scene feature and/or object that accurately corresponds to the real-world scene feature and/or object can be time-consuming, laborious, and inefficient. Therefore, there exists a need for automatically identifying and pairing a scene feature and/or object in road data that is captured in a real-world environment with a corresponding (or equivalent) simulated scene feature and/or object in simulation data. Further, there exists a need for updating simulation data based on any difference(s) or divergence(s) between the scene feature and/or object in the road data and its synthetic counterpart in the simulation data to validate and improve the simulation data to be as realistic as possible. The road data as used herein (also referred to as real-world driving data) refers to data collected by a vehicle in a real-world environment. For example, the road data can include sensor data collected by a vehicle, such as an AV, in a real-world environment while the vehicle navigates the real-world environment. The vehicle can collect the road data using one or more sensors of the vehicle such as, for example and without limitation, one or more light detection and ranging (LIDAR) sensors, one or more radio detection and ranging (RADAR) sensors, one or more camera or image sensors, one or more inertial measurement units (IMUs), one or more ultrasonic or acoustic sensors, and/or any other sensors.

Described herein are systems, apparatuses, processes (also referred to as methods), and computer-readable media (collectively referred to as “systems and techniques”) for identifying an object in road data that corresponds to a simulated representation in simulation data using machine learning. For example, the systems and techniques described herein can be used to identify an object in real-world driving data (e.g., road data) that corresponds to a simulated object in simulation data using machine learning to validate the simulation data based on any differences and/or similarities/matches between the object identified in the real-world driving data and its counterpart in the simulation data. In some examples, the systems and techniques can validate simulation data by determining any difference between the object in road data and the simulated object in simulation data and/or a degree of the difference if there exists any difference between the object in road data and the simulated object in simulation data. The systems and techniques described herein can leverage road data that has been captured in a real-world environment to ensure realistic simulations by creating a validation pipeline for simulated representations (e.g., assets) in simulation data. In some examples, the systems and techniques described herein can help identify an object in road data that corresponds to (and/or is equivalent to) a simulated representation of an object in simulation data and further identify a difference between the object in road data and the simulated representation of the object in simulation data to decrease the degree of difference so that a gap between the simulation and the real-world environment can be reduced or eliminated.

To illustrate, the systems and techniques described herein can receive simulation data (e.g., synthetic data in a simulation (e.g., virtual) environment) that includes various simulated driving scenarios for testing AVs. The simulation data can include virtual assets (e.g., objects, elements, and/or features) that include a simulated scene. For example, an asset can include a synthetic/simulated representation of a real entity (e.g., a physical entity in the real world) such as vehicles (e.g., an AV, a car, a truck, a motorcycle, a bicycle, an aircraft, a tank, etc.), pedestrians, animals, buildings, traffic signs, trees, plants, or any other applicable static and/or dynamic objects that can be present in a simulated scene. In some cases, simulation data includes fine-grained information (e.g., details) about assets such as their characteristics, properties, types or classes/categories, features, context, and/or attributes (e.g., a dimension, a color, a model version, a material, etc.). For example, if simulation data includes a simulated representation of a vehicle, the simulation data can include any properties or characteristics associated with the vehicle such as a dimension, a color, a make, a model version, a material, a size of components/parts of the vehicle, etc.

Furthermore, the systems and techniques described herein can receive road data (e.g., real-world data or real-world driving data) that is collected by an AV while navigating in a real-world environment. The road data can include sensor data (e.g., real-world sensor data), which is collected by one or more sensors of an AV while navigating in a real-world environment. The sensor data can measure and/or can be descriptive of the real-world environment (and/or objects/elements in the real-world environment) such as nearby objects perceived within a vicinity of the AV. Such objects can include, for example and without limitation, vehicles (e.g., an AV, a car, a truck, a motorcycle, a bicycle, an aircraft, a tank, etc.), pedestrians, animals, buildings, traffic signs, trees, plants, and/or any other applicable static and/or dynamic objects that can be present in the real-world driving environment.

In some cases, a machine learning model can be used to pair an object identified/captured in road data with its equivalent asset in simulation data. A machine learning model can be trained to learn to identify an object in road data (e.g., real-world driving data) that matches an asset in simulation data. By comparing the asset in simulation data against the object identified in road data with fine granularity (e.g., with respect to detailed characteristics, properties, features, and/or attributes of the asset and the object), the asset can validate whether its simulated representation is as real as the object identified in real-world driving data. For example, a machine learning model can identify and pair a simulated representation of a 2020 Chevrolet Bolt in simulation data and 2020 Chevrolet Bolt identified in real-world driving data. Further, a comparison between the simulated representation of 2020 Chevrolet Bolt in simulation data and a 2020 Chevrolet Bolt identified in real-world driving data can be made to determine if the simulated representation accurately models its equivalence identified in real-world driving data.

In some aspects, the systems and techniques described herein can determine any difference or discrepancy between an asset in simulation data (e.g., a simulated representation of an object in simulation data) and its equivalent object identified in real-world driving data. The systems and techniques can determine any difference or discrepancy with respect to one or more characteristics, properties, features, and/or attributes between an asset in simulation data and its equivalent object identified in road data. For example, the systems and techniques described here can identify a source/cause of the difference or discrepancy between an asset in simulation data and its equivalent object identified in real-world driving data so the systems and techniques described herein can determine which course of action can be taken to improve the simulation data. In some examples, the systems and techniques described herein can improve the simulation data to make the asset in simulation data more realistic (e.g., more closely match, mirror/emulate, and/or resemble its equivalent object identified in the real-world driving data).

In some examples, if a difference or discrepancy between an asset in simulation data and its equivalent object identified in real-world driving data is attributed to one or more properties of the object (e.g., a dimension, a color, a model version, a material, etc.), the systems and techniques described herein can modify the asset in the simulation to emulate the property of the real-world object that is attributed to the difference. For example, if a height of a simulated representation of a 2020 Chevrolet Bolt in simulation data is one inch shorter than the height of a 2020 Chevrolet Bolt identified in road data, the height of the asset in simulation data (e.g., the 2020 Chevrolet Bolt in the simulation data) can be modified (e.g., extended/enlarged to be one inch taller) to match what is observed in real-world driving data (e.g., road data) so that the gap between the asset in simulation data and its equivalent real-world object can be reduced or eliminated.

In some aspects, simulation data (e.g., simulation sensor data, virtual content, road data replayed in simulation, etc.) can be captured by one or more synthetic/simulated sensors (e.g., a virtual/simulated/synthetic camera sensor, LiDAR sensor, RADAR sensor, IMU, time-of-flight (TOF) sensor, etc.) of a simulated AV in a simulation scene. In such cases, the systems and techniques described herein can determine whether any difference or discrepancy between an asset captured by synthetic/simulated sensor(s) in simulation data and its equivalent object in road data is attributed to the synthetic/simulated sensor(s). If the difference or discrepancy is attributed to the synthetic/simulated sensor(s) of the simulated AV, the systems and techniques described herein can update the synthetic/simulated sensor(s) to emulate the AV sensor(s) that are used to capture the road data. For example, simulation data can include LiDAR sensor data, which is captured by a synthetic/simulated LiDAR sensor of a simulated AV in a simulation scene. In this example, the systems and techniques described herein can compare the LiDAR intensity value measured by a synthetic LiDAR sensor in simulation data against the LiDAR intensity value measured by a real-world AV LiDAR sensor in road data with respect to an equivalent object. If the comparison indicates that there is any difference or discrepancy between two LiDAR intensity values, the synthetic LiDAR sensor of a simulated AV can be updated to emulate the real-world AV LiDAR sensor.

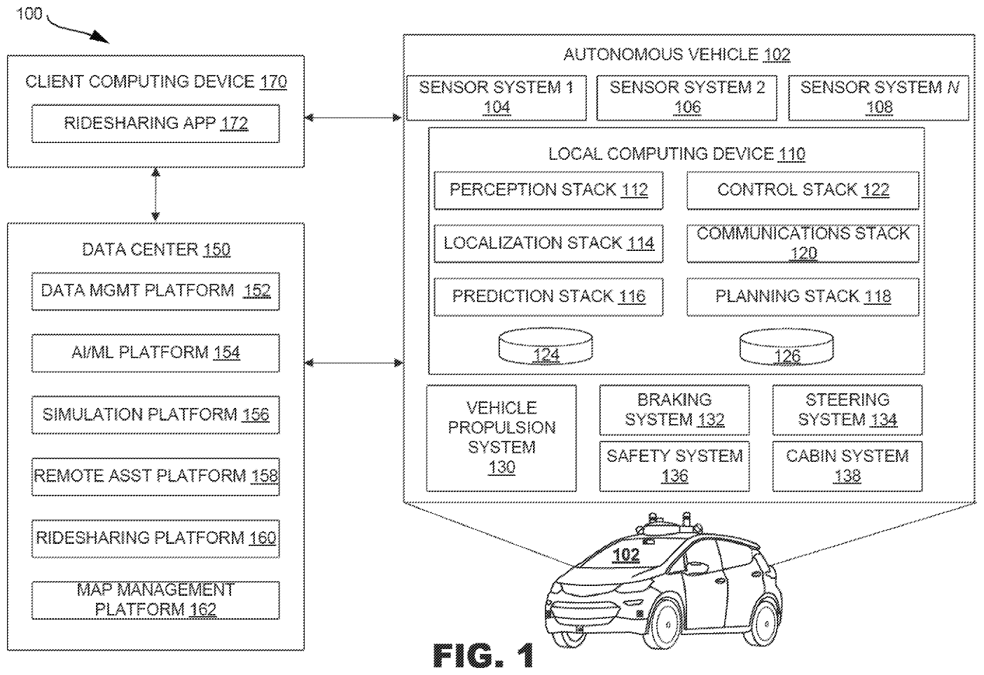

Various examples of the systems and techniques described herein for identifying an object in road data corresponding to a simulated representation in simulation data using machine learning are illustrated in FIG. 1 through FIG. 6 and described below.

FIG. 1 is a diagram illustrating an example autonomous vehicle (AV) environment 100, according to some examples of the present disclosure. One of ordinary skill in the art will understand that, for the AV environment 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LIDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform (e.g., map management platform 162); modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. The client computing device 170 can be a customer's mobile computing device or a computing device integrated with the AV 102 (e.g., the local computing device 110). The ridesharing platform 1160 can receive requests to pick up or drop off from the ridesharing application 1172 and dispatch the AV 1102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some examples, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

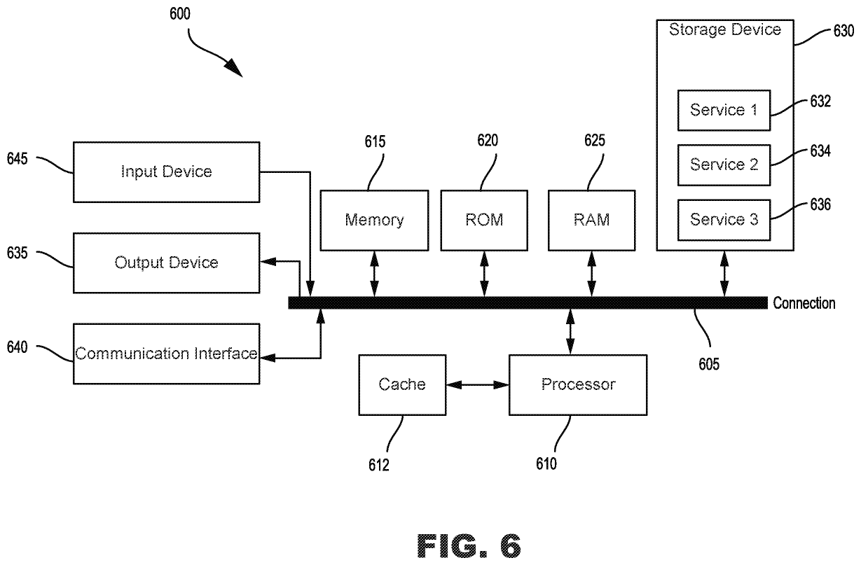

While the AV 102, the local computing device 110, and the AV environment 100 are shown to include certain systems and components, one of ordinary skill will appreciate that the AV 102, the local computing device 110, and/or the AV environment 100 can include more or fewer systems and/or components than those shown in FIG. 1. For example, the AV 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 6.

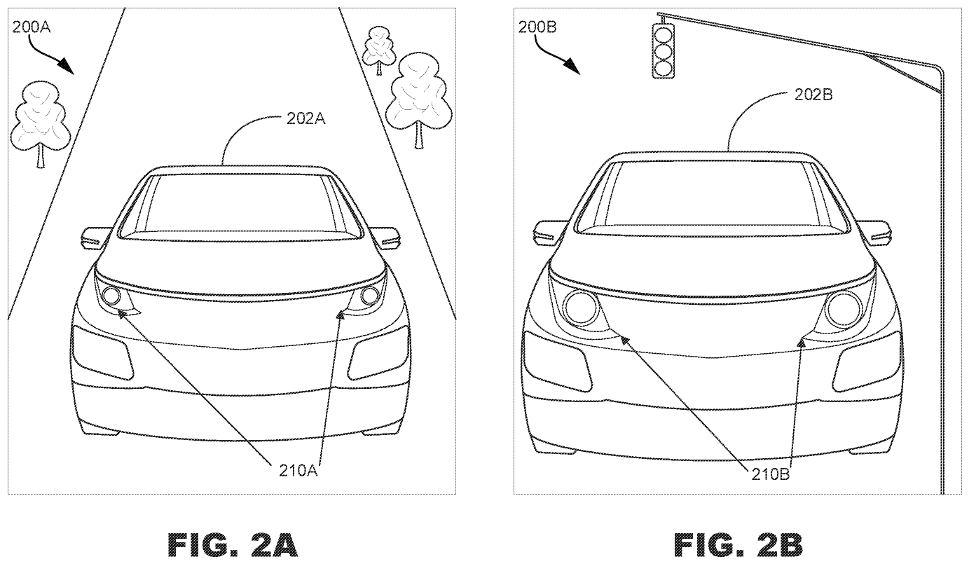

FIGS. 2A and 2B illustrate a comparison between a simulated asset in a simulation scene 200A and its equivalent object identified in a real-world environment 200B. For example, FIG. 2A illustrates an example simulated vehicle 202A (e.g., a simulated representation of a vehicle) in simulation data that includes and/or is descriptive of a simulation scene 200A. FIG. 2B illustrates an example real-world vehicle 202B captured in road data (e.g., real-world driving data) that corresponds to (or is equivalent to) the simulated vehicle 202A where the road data is captured by an AV (e.g., the AV 102 as illustrated in FIG. 1) while navigating in a real-world environment 200B.

In some aspects, simulation data, which includes and/or is descriptive of the simulated scene 200A, can include detailed information associated with one or more assets that are represented in the simulated scene 200A. For example, the simulation data can include information about characteristics, properties, features, and/or attributes of the simulated vehicle 202A (e.g., a dimension, a size, a color, a make, a year, a model, a material, a position/location/angle of each component, a distance between components/parts, etc.).

In some examples, a machine learning model can be used to identify the real-world vehicle 202B captured in real-world road data that corresponds to (and/or is equivalent to) the simulated vehicle 202A. The machine learning model (e.g., a neural network) can be trained to find a match in road data so that an asset in simulation data and its counterpart in road data can be paired together and compared to each other. The machine learning model classifies and identifies an object at a granularity level. In other words, a machine learning model is trained to identify an object in road data that matches the type, characteristics, properties, features, and/or attributes (e.g., a dimension, a size, a color, a make, a year, a model, a material, a position/location/angle of each component, a distance between components/parts, etc.) of the simulated asset provided in simulation data rather than relying on a label or general classification. For example, when simulation data and road data are provided to a machine learning model, an output of the machine learning model can include a pair of the simulated vehicle 202A and the real-world vehicle 202B, for example, that has the identical vehicle make, year, and model. The use of a machine learning model can automate the process of inspecting an extensive amount of simulation data (e.g., also referred to as bag data) to detect the equivalent object between simulation data and road data and help improve the quality of simulation data including simulated representations of assets to be as realistic as possible (e.g., to better match, resemble, and/or mirror/emulate a corresponding object in road data).

In some cases, a machine learning model can compare the simulated vehicle 202A and the real-world vehicle 202B with each other to identify any difference or discrepancy between them and determine if the simulated vehicle 202A accurately models its equivalent real-world vehicle 202B. In some examples, the difference can be attributed to one or more properties of the simulated vehicle 202A and the real-world vehicle 202B such as a dimension (e.g., a height, width, or length) of the vehicle, a dimension of each component/parts of the vehicle (e.g., a length of window wipers, a size of a rear window, etc.), a type of material for each component/parts (e.g., a metal, glass, plastic, rubber, etc.), a distance between parts (e.g., a distance between a driver-side door and a front bumper, a distance between two headlights, etc.).

In the illustrative example shown in FIGS. 2A and 2B, the systems and techniques described herein can determine that the size of the simulated vehicle 202A is smaller than the size of the real-world vehicle 202B and increase the size of the simulated vehicle 202A to emulate/match the size of the real-world vehicle 202B. The differences in the size of the simulated vehicle 202A and the real-world vehicle 202B can impact the difficulty or ease in maneuvering in smaller spaces, may affect the kinematics of the vehicle, and/or may affect the visibility of the vehicle to other agents on the road. The systems and techniques described herein can detect any difference between the simulated vehicle 202A and the real-world vehicle 202B and modify the simulated vehicle 202A not only to make the simulation data (e.g. the simulation scene and/or simulated representations therein) more realistic but also to avoid any discrepancies in behaviors/outcomes due to the difference (e.g., the difference in the size of the vehicle). As follows, the systems and techniques described herein can avoid or eliminate any differences in behaviors/outcomes/interactions of an AV and/or other scene agents (e.g. relative to the real world) that may be caused or influenced by the vehicle having a different size in the simulation than in the real world.

In some aspects, the systems and techniques described herein can determine a degree of any difference between the simulated vehicle 202A and the real-world vehicle 202B and/or determine a degree of impact that a difference may have (e.g., impact on behaviors/outcomes, kinematics of a vehicle and/or a scene, visibility of the object to other agents) to determine whether any update or modification to the simulated vehicle 202A to be made. In the illustrative example shown in FIGS. 2A and 2B, the systems and techniques described herein can determine that the size of the front headlights 210A on the simulated vehicle 202A and the front headlights 210B on the real-world vehicle 202B differ. Once a difference is identified, the systems and techniques described herein can modify the simulated vehicle 202A (e.g., update the simulation data) to emulate the properties of the real-world vehicle 202B. For example, the size of the front headlights 210A as represented in the simulated vehicle 202A can be enlarged to match the size of the front headlights 210B of the real-world vehicle 202B. This way, the simulation data can be validated based on real-world road data and improved to be close to a real-world representation. Alternatively, the systems and techniques described herein can determine any impact that the difference in the size of the front bumpers may have. If the impact is minor, the degree of impact is below a threshold, and/or the difference is merely cosmetic difference, then the systems and techniques described herein can determine that the simulated vehicle 202A does not need to be updated or modified to match the size of the front bumpers of the real-world vehicle 202B.

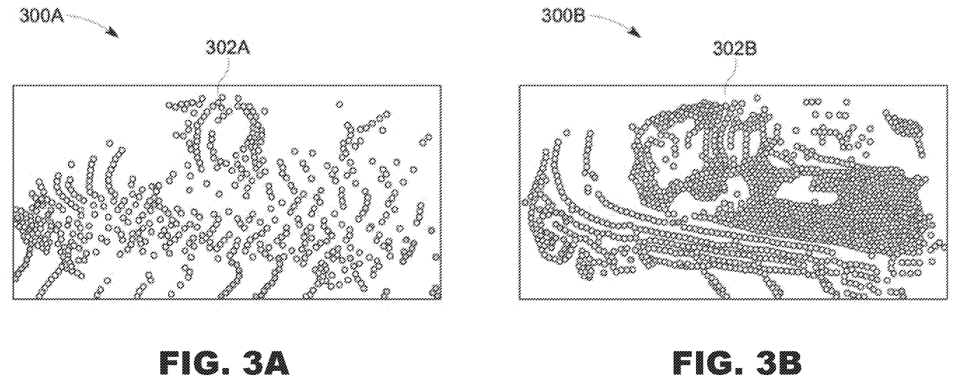

FIGS. 3A and 3B illustrate a comparison between a LiDAR intensity image of an asset in a simulated scene and a LiDAR intensity image of its equivalent object in a real-world environment. For example, FIG. 3A illustrates an example LiDAR intensity image 300A of a simulated vehicle 302A based on LiDAR data collected by a synthetic LiDAR sensor of a simulated AV in simulation. FIG. 3B illustrates an example LiDAR intensity image 300B of a real-world vehicle 302B based on LiDAR data collected by a real-world LiDAR sensor in a real-world environment.

As previously described, a machine learning model can identify a real-world vehicle 302B in real-world driving data that corresponds to the simulated vehicle 302A in simulation data. In some examples, the systems and techniques described herein can compare (e.g., via a machine learning model) sensor data of the simulated vehicle 302A that is captured by a synthetic sensor of a simulated AV against sensor data of the real-world vehicle 302B that is captured by the corresponding real-world sensor (e.g., sensor system 104-108 as illustrated in FIG. 1) of an AV (e.g., the AV 102 as illustrated in FIG. 1). Examples of sensors can include, without limitation, a camera sensor, a LiDAR sensor, a RADAR sensor, an IMU, a TOF sensor, etc.).

Referring to FIG. 3A, the LiDAR intensity image 300A of the simulated vehicle 302A is based on sensor data captured by a synthetic LiDAR sensor while a simulated AV is navigating in a simulated scene. Also, the LiDAR intensity image 300B of the real-world vehicle 302B, which is equivalent to the simulated vehicle 302A (e.g., based on an output of the machine learning model as described with respect to FIGS. 2A and 2B) is based on real-world driving data that is captured by a real-world LiDAR sensor. In some examples, the LiDAR intensity image 300A of the simulated vehicle 302A can be compared with the LiDAR intensity image 300B of the real-world vehicle 302B to determine any difference or discrepancy. The difference in the LiDAR intensity image and/or the pixel intensities (e.g., intensity values measured by the LiDAR sensor) can potentially impact the simulation relative to what happened/happens in the real world.

In some examples, the comparison can indicate whether the difference between the LiDAR intensity image 300A and the LiDAR intensity image 300B (or the difference between the sensor data captured by a synthetic LiDAR sensor and the sensor data captured by a real-world LiDAR sensor) is attributed to one or more properties of the object (e.g., the simulated vehicle 302A or the real-world vehicle 302B) or a sensor that has been used to capture the respective sensor data.

In some cases, the difference in the LiDAR intensity image of the same object can be caused by different types of materials since different types of materials (e.g., metal, glass, plastic, wood, rubber, etc.) would have different reflectivities and LiDAR transmissions. By comparing the LiDAR intensities between the simulated vehicle 302A and the real-world vehicle 302B, the systems and techniques described herein can determine if a material of any parts of the simulated vehicle 302A needs to be updated to emulate the material of the real-world vehicle 302B.

In some examples, the difference in the LiDAR intensity image of the same object can be attributed to a LiDAR sensor that has been used to capture the respective data (e.g., a location/position of the sensor, a placement and/or position of the sensor, a geometry and/or arrangement of the sensor, a resolution of the sensor, etc.). As follows, the systems and techniques described herein can modify/update the sensor system of a simulated AV, which was used to capture the sensor data with respect to the simulated vehicle 302A to emulate the properties/features of the real-world sensor system that was used to capture the sensor data with respect to the real-world vehicle 302B.

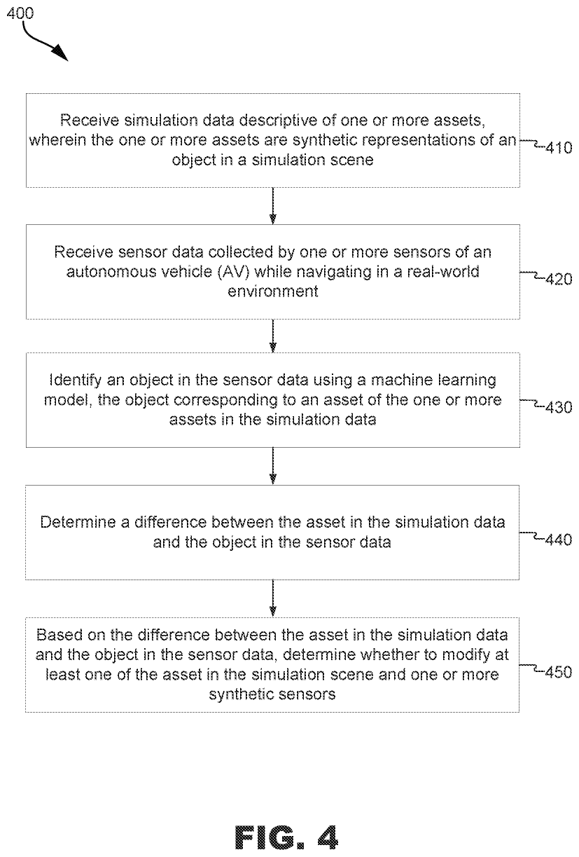

FIG. 4 is a flowchart illustrating an example process 400 for identifying an object in road data corresponding to a simulated representation in simulation data using machine learning. Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence.

At block 410, the process 400 can include receiving simulation data descriptive of one or more assets, wherein the one or more assets are synthetic representations of an object in a simulation scene. For example, the systems and techniques described herein can receive simulation data that includes various simulated driving scenarios for testing AVs (e.g., the AV 102 as illustrated in FIG. 1). The simulation data can include virtual assets (e.g., the simulated vehicle 202A or 302A). Non-limiting examples of assets can include vehicles (e.g., an AV, a car, a truck, a motorcycle, a bicycle, an aircraft, a tank, etc.), pedestrians, animals, buildings, traffic signs, trees, plants, or any other applicable static and/or dynamic objects that can be present in a simulated scene. Further, the simulation data includes detailed information associated with assets, for example, their characteristics, properties, features, and/or attributes (e.g., a dimension, a color, a model version, a material, etc.). For example, for the simulated vehicle 202A or 302A, the simulation data can include, in addition to its label or general classification (e.g., a “vehicle”), a description of any properties or characteristics such as a dimension, a color, a make, a model version, a material, a size of components/parts of the vehicle, etc.

At block 420, the process 400 can include receiving sensor data collected by one or more sensors of an AV while navigating in a real-world environment. For example, the systems and techniques described herein can receive real-world road data/sensor data collected by one or more sensors (e.g., the sensor systems 104-108) of the AV 102 while navigating in a real-world environment. More specifically, the real-world sensor data can be descriptive of the real-world objects (e.g., the real-world vehicle 202B or 302B) perceived around the AV.

At block 430, the process 400 can include identifying an object in the sensor data using a machine learning model, the object corresponding to an asset of the one or more assets in the simulation data. For example, the systems and techniques described herein can identify the real-world vehicle 202B or 302B that corresponds to (or is equivalent to) the simulated vehicle 202A or 302A, respectively, using a machine learning model. Further, the systems and techniques can compare the simulated vehicle 202A or 302A against the real-world vehicle 202B or 302B, respectively, to determine if there is any difference between them.

At block 440, the process 400 can include determining a difference between the asset in the simulation data and the object in the sensor data. For example, the systems and techniques described herein can determine any difference or discrepancy between the simulated vehicle 202A or 302A and the real-world vehicle 202B or 302B, respectively, with respect to one or more characteristics, properties, features, and/or attributes of the simulated vehicle 202A or 302A and the real-world vehicle 202B or 302B.

In some examples, a difference between the asset in the simulation data (e.g., the simulated vehicle 202A or 302A) and the object in the real-world sensor data (e.g., the real-world vehicle 202B or 302B) can be determined using a neural network. For example, a neural network can be used to identify any difference or discrepancy between the simulated vehicle 202A or 302A and the real-world vehicle 202B or 302B, for example, by identifying patterns and extracting features.

Furthermore, the process 400 can include determining whether the difference between the asset in the simulation and the object in the sensor data is attributed to one or more properties of the object or one or more synthetic sensors that are used to capture the simulation data. For example, the systems and techniques described herein can determine that the difference between the simulated vehicle 202A or 302A and the real-world vehicle 202B or 302B, respectively, is attributed to one or more properties of the object a dimension (e.g., a height, width, or length) of the vehicle, a dimension of each component/parts of the vehicle (e.g., a length of window wipers, a size of a rear window, etc.), a type of material for each component/parts (e.g., a metal, glass, plastic, rubber, etc.), a distance between parts (e.g., a distance between a driver-side door and a front bumper, a distance between two headlights, etc.).

In another example, the systems and techniques described herein can determine that the difference between the simulated vehicle 202A or 302A and the real-world vehicle 202B or 302B, respectively, is attributed to synthetic sensor(s) such as (e.g., a camera sensor, a LiDAR sensor, a RADAR sensor, an IMU, a TOF sensor, etc.) of a simulated AV that have been used to capture the simulated vehicle 202A or 202B. The difference that is caused by the synthetic sensor(s) can be associated with a location/position of the synthetic sensors implemented by the simulated AV (e.g., which can impact the field-of-view or field-of-coverage of the sensors, among other things), a placement and/or position (e.g., angle, azimuth, orientation, elevation, etc.) of the synthetic sensors, a geometry and/or arrangement of the synthetic sensors with respect to each other and/or the simulated AV, a combination of different types of synthetic sensors, a resolution of the synthetic sensors, a scanning pattern of one or more of the synthetic sensors, a frame rate of one or more of the synthetic sensors, a firmware version of the synthetic sensors, a frequency of one or more of the synthetic sensors, an exposure of one or more synthetic camera devices implementing one or more synthetic camera sensors, an operating temperature of the synthetic sensors, a power mode of the synthetic sensors (e.g., a power/energy saving mode), etc.

In some cases, two or more assets of the same in simulation data can be compared to each other and the real-world object to confirm that the difference between the asset in the simulation data and the real-world object identified in the real-world sensor data is attributed to a synthetic sensor of a simulated AV that has been used to capture the simulated asset. For example, a plurality of simulation scenes that may include the simulated vehicle 202A or 302A can be collected and determine if the same type of difference is located in the same type of material of the object or region. This way, it can be inferred that the difference between the simulated asset and the real-world object may be with the sensor rather than the particular simulated asset.

In some examples, the simulation data of an asset that is captured by a synthetic sensor can be compared against real-world road data of the asset's equivalent real-world object, in which the real-world road data is captured by a real-world sensor that corresponds to the synthetic sensor. For example, the simulation data can include LiDAR sensor data, which is captured by a synthetic LiDAR sensor of a simulated AV (e.g., the LiDAR intensity image 300A as illustrated in FIG. 3A). As follows, the LiDAR intensity image 300A of the simulated vehicle 302A can be compared with the LiDAR intensity image 300B of the real-world vehicle 302B, for example, based on the LiDAR intensity values. In some examples, since different types of materials would have different LiDAR transmissions and therefore, result in varying LiDAR intensity values, any difference in LiDAR intensities can indicate that any location where the difference in LiDAR intensity values is detected would have a different type of materials than the one in the real-world object. In other examples, the difference in LiDAR intensity values can be caused by the LiDAR sensor itself, for example, due to various characteristics or properties of the LiDAR sensor (e.g., a location/position of the sensor, a placement and/or position of the sensor, a geometry and/or arrangement of the sensor, a resolution of the sensor, etc.).

At block 450, the process 400 can include based on the difference between the asset in the simulation data and the object in the sensor data, determining whether to modify at least one of the asset in the simulation scene and one or more synthetic sensors. If the difference between an asset in simulation data and its equivalent object identified in real-world driving data is attributed to one or more properties of the object (e.g., a dimension, a color, a model version, a material, etc.), the systems and techniques described herein can modify the asset in the simulation to emulate the property of the real-world object that is attributed to the difference so that the gap between the asset in simulation data and its equivalent real-world object can be reduced. For example, as illustrated in FIGS. 2A and 2B, the systems and techniques described herein can adjust the size of the simulated front headlights (eg., front headlights 210A) of the simulated vehicle 202A to be identical to the size of the headlights (e.g., front headlights 210B) of the real-world vehicle 202B.

In some cases, if the difference between an asset in simulation data and its equivalent object identified in real-world driving data is attributed to one or more synthetic sensors, the systems and techniques described herein can update the synthetic sensor of the simulated AV (e.g., characteristics or properties of the synthetic sensor as previously described) to emulate the real-world sensors so that the quality of the simulation data can be improved (or be as close to real-world driving data).

In some examples, the process 400 can include determining a degree of the difference between the asset in the simulation data and the object identified in the sensor data. If the degree of the difference exceeds a threshold, the systems and techniques described herein can modify the simulated asset or the synthetic sensor to emulate its equivalent real-world object or the real-world sensor. If the degree of the difference is below a threshold or is determined to be minor, the systems and techniques can keep the simulated asset or the synthetic sensor. In some examples, the systems and techniques described herein can determine the degree of the difference between the asset in the simulation data and the object identified in the sensor data using machine learning techniques. In some cases, the systems and techniques can determine the degree of the difference by representing intermediate machine learning layers (also often referred to as features) that have intermediate representations of the object and producing the difference between the features in the simulation data and the sensor data. In some aspects, the systems and techniques can determine the degree of the difference based on sensor measurements (e.g., LiDAR measurements) such as an average intensity in LiDAR, a distribution of LiDAR intensities, a size of the object, a number of LiDAR hits on the object, and so on. More specifically, the systems and techniques can compare the sensor measurements in the simulation data and corresponding sensor measurements in the sensor data to determine the degree of the difference.

For example, the systems and techniques described herein can determine whether any difference between the asset in the simulation data and the object identified in the sensor data can impact behaviors/outcomes/interactions of an AV and/or other scene agents relative to the real world, the kinematics of the vehicle, and/or the visibility to other agents on the road. The systems and techniques described herein can update or modify the asset in the simulation data not only to make the simulation data more realistic but also to avoid any discrepancies in behaviors/outcomes due to the difference.

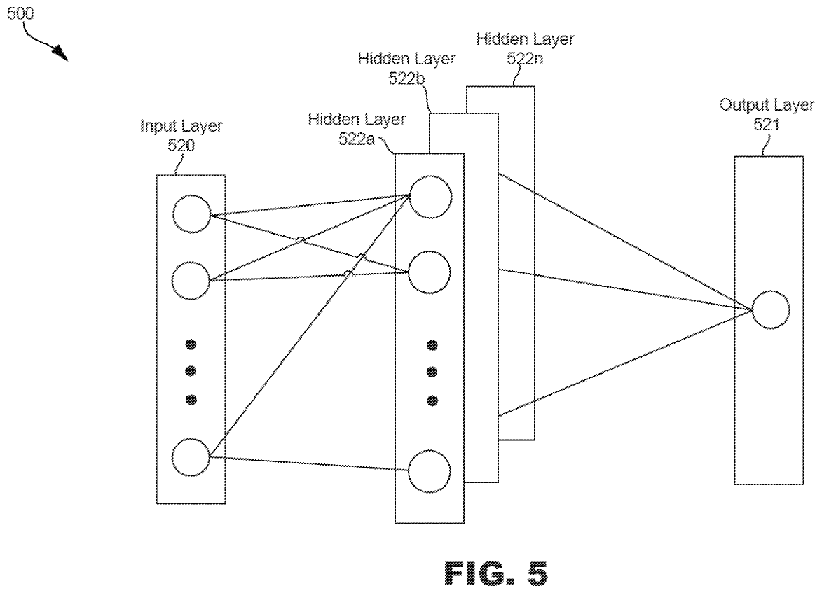

In FIG. 5, the disclosure now turns to a further discussion of models that can be used through the environments and techniques described herein. FIG. 5 is an example of a deep learning neural network 500 that can be used to implement all or a portion of the systems and techniques described herein (e.g., neural network 500 can be used to implement a perception module (or perception system) as discussed above). An input layer 520 can be configured to receive sensor data and/or data relating to an environment surrounding an AV. The neural network 500 includes multiple hidden layers 522a, 522b, through 522n. The hidden layers 522a, 522b, through 522n include “n” number of hidden layers, where “n” is an integer greater than or equal to one. The number of hidden layers can be made to include as many layers as needed for the given application. The neural network 500 further includes an output layer 521 that provides an output resulting from the processing performed by the hidden layers 522a, 522b, through 522n. In one illustrative example, the output layer 521 can provide estimated treatment parameters, that can be used/ingested by a differential simulator to estimate a patient treatment outcome.

The neural network 500 is a multi-layer neural network of interconnected nodes. Each node can represent a piece of information. Information associated with the nodes is shared among the different layers and each layer retains information as information is processed. In some cases, the neural network 500 can include a feed-forward network, in which case there are no feedback connections where outputs of the network are fed back into itself. In some cases, the neural network 500 can include a recurrent neural network, which can have loops that allow information to be carried across nodes while reading in input.

Information can be exchanged between nodes through node-to-node interconnections between the various layers. Nodes of the input layer 520 can activate a set of nodes in the first hidden layer 522a. For example, as shown, each of the input nodes of the input layer 520 is connected to each of the nodes of the first hidden layer 522a. The nodes of the first hidden layer 522a can transform the information of each input node by applying activation functions to the input node information. The information derived from the transformation can then be passed to and can activate the nodes of the next hidden layer 522b, which can perform their own designated functions. Example functions include convolutional, up-sampling, data transformation, and/or any other suitable functions. The output of the hidden layer 522b can then activate nodes of the next hidden layer, and so on. The output of the last hidden layer 522n can activate one or more nodes of the output layer 521, at which an output is provided. In some cases, while nodes in the neural network 500 are shown as having multiple output lines, a node can have a single output and all lines shown as being output from a node represent the same output value.

In some cases, each node or interconnection between nodes can have a weight that is a set of parameters derived from the training of the neural network 500. Once the neural network 500 is trained, it can be referred to as a trained neural network, which can be used to classify one or more activities. For example, an interconnection between nodes can represent a piece of information learned about the interconnected nodes. The interconnection can have a tunable numeric weight that can be tuned (e.g., based on a training dataset), allowing the neural network 500 to be adaptive to inputs and able to learn as more and more data is processed.

The neural network 500 is pre-trained to process the features from the data in the input layer 520 using the different hidden layers 522a, 522b, through 522n in order to provide the output through the output layer 521.

In some cases, the neural network 500 can adjust the weights of the nodes using a training process called backpropagation. A backpropagation process can include a forward pass, a loss function, a backward pass, and a weight update. The forward pass, loss function, backward pass, and parameter/weight update is performed for one training iteration. The process can be repeated for a certain number of iterations for each set of training data until the neural network 500 is trained well enough so that the weights of the layers are accurately tuned.

To perform training, a loss function can be used to analyze error in the output. Any suitable loss function definition can be used, such as a Cross-Entropy loss. Another example of a loss function includes the mean squared error (MSE), defined as E_total=Σ(½ (target-output)\hat{ }2). The loss can be set to be equal to the value of E_total.

The loss (or error) will be high for the initial training data since the actual values will be much different than the predicted output. The goal of training is to minimize the amount of loss so that the predicted output is the same as the training output. The neural network 500 can perform a backward pass by determining which inputs (weights) most contributed to the loss of the network, and can adjust the weights so that the loss decreases and is eventually minimized.

The neural network 500 can include any suitable deep network. One example includes a Convolutional Neural Network (CNN), which includes an input layer and an output layer, with multiple hidden layers between the input and out layers. The hidden layers of a CNN include a series of convolutional, nonlinear, pooling (for downsampling), and fully connected layers. The neural network 500 can include any other deep network other than a CNN, such as an autoencoder, Deep Belief Nets (DBNs), Recurrent Neural Networks (RNNs), among others.

As understood by those of skill in the art, machine-learning based classification techniques can vary depending on the desired implementation. For example, machine-learning classification schemes can utilize one or more of the following, alone or in combination: hidden Markov models; RNNs; CNNs; deep learning; Bayesian symbolic methods; Generative Adversarial Networks (GANs); support vector machines; image registration methods; and applicable rule-based systems. Where regression algorithms are used, they may include but are not limited to: a Stochastic Gradient Descent Regressor, a Passive Aggressive Regressor, etc.

Machine learning classification models can also be based on clustering algorithms (e.g., a Mini-batch K-means clustering algorithm), a recommendation algorithm (e.g., a Minwise Hashing algorithm, or Euclidean Locality-Sensitive Hashing (LSH) algorithm), and/or an anomaly detection algorithm, such as a local outlier factor. Additionally, machine-learning models can employ a dimensionality reduction approach, such as, one or more of: a Mini-batch Dictionary Learning algorithm, an incremental Principal Component Analysis (PCA) algorithm, a Latent Dirichlet Allocation algorithm, and/or a Mini-batch K-means algorithm, etc.

FIG. 6 illustrates an example processor-based system with which some aspects of the subject technology can be implemented. For example, processor-based system 600 can be any computing device making up, the local computing device 110, the client computing device 170 executing the ridesharing application 172, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some examples, computing system 600 is a distributed system in which the functions described in this disclosure can be distributed within a datacenter, multiple data centers, a peer network, etc. In some cases, one or more of the described system components represents many such components each performing some or all of the function for which the component is described. In some cases, the components can be physical or virtual devices.

Example system 600 includes at least one processing unit (CPU or processor) 610 and connection 605 that couples various system components including system memory 615, such as read-only memory (ROM) 620 and random-access memory (RAM) 625 to processor 610. Computing system 600 can include a cache of high-speed memory 612 connected directly with, in close proximity to, and/or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 can include an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/9G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L9/L #), resistive random-access memory (RRAM/ReRAM), phase change memory (PCM), spin transfer torque RAM (STT-RAM), another memory chip or cartridge, and/or a combination thereof.

Storage device 630 can include software services, servers, services, etc., that when the code that defines such software is executed by the processor 610, causes the system to perform a function. In some examples, a hardware service that performs a particular function can include the software component stored in a computer-readable medium in connection with the necessary hardware components, such as processor 610, connection 605, output device 635, etc., to carry out the function.

As understood by those of skill in the art, machine-learning techniques can vary depending on the desired implementation. For example, machine-learning schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A system comprising: a memory; and one or more processors coupled to the memory, the one or more processors being configured to: receive simulation data descriptive of one or more assets, wherein the one or more assets are synthetic representations of an object in a simulation scene; receive sensor data collected by one or more sensors of an autonomous vehicle (AV) while navigating in a real-world environment; identify an object in the sensor data using a machine learning model, the object corresponding to an asset of the one or more assets in the simulation data; determine a difference between the asset in the simulation data and the object in the sensor data; and based on the difference between the asset in the simulation data and the object in the sensor data, determine whether to modify at least one of the assets in the simulation scene and one or more synthetic sensors.

Aspect 2. The system of Aspect 1, wherein the difference is attributed to a property of the object, the property comprising at least one of a geometry, a color, and a material of the object.

Aspect 3. The system of Aspect 2, wherein determining whether to modify at least one of the assets in the simulation scene and one or more synthetic sensors includes modifying the asset in the simulation scene to emulate the property of the object that is attributed to the difference.

Aspect 4. The system of any of Aspects 1 to 3, wherein the difference is attributed to one or more synthetic sensors that are used to capture the simulation data in the simulation scene.

Aspect 5. The system of Aspect 4, wherein determining whether to modify at least one of the asset in the simulation scene and one or more synthetic sensors includes updating the one or more synthetic sensors to emulate the one or more sensors of the AV that are used to capture the sensor data.

Aspect 6. The system of any of Aspects 1 to 5, wherein the one or more sensors of the AV include at least one of a Light Detection and Ranging (LiDAR) sensor, a Radio Detection and Ranging (RADAR), a camera, an inertial measurement unit (IMU), and a Time-of-Flight camera.

Aspect 7. The system of any of Aspects 1 to 6, wherein the difference is based on an intensity value measured by a Light Detection and Ranging (LiDAR) sensor.

Aspect 8. The system of any of Aspects 1 to 7, wherein determining whether to modify at least one of the asset in the simulation scene and one or more synthetic sensors includes determining a degree of the difference between the asset in the simulation data and the object in the sensor data using a neural network.

Aspect 9. A method comprising: receiving simulation data descriptive of one or more assets, wherein the one or more assets are synthetic representations of an object in a simulation scene; receiving sensor data collected by one or more sensors of an autonomous vehicle (AV) while navigating in a real-world environment; identifying an object in the sensor data using a machine learning model, the object corresponding to an asset of the one or more assets in the simulation data; determining a difference between the asset in the simulation data and the object in the sensor data; and based on the difference between the asset in the simulation data and the object in the sensor data, determining whether to modify at least one of the assets in the simulation scene and one or more synthetic sensors.

Aspect 10. The method of Aspect 9, wherein the difference is attributed to a property of the object, the property comprising at least one of a geometry, a color, and a material of the object.

Aspect 11. The method of Aspect 10, wherein determining whether to modify at least one of the assets in the simulation scene and one or more synthetic sensors includes modifying the asset in the simulation scene to emulate the property of the object that is attributed to the difference.

Aspect 12. The method of any of Aspects 9 to 11, wherein the difference is attributed to one or more synthetic sensors that are used to capture the simulation data in the simulation scene.

Aspect 13. The method of Aspect 12, wherein determining whether to modify at least one of the assets in the simulation scene and one or more synthetic sensors includes updating the one or more synthetic sensors to emulate the one or more sensors of the AV that are used to capture the sensor data.

Aspect 14. The method of any of Aspects 9 to 13, wherein the one or more sensors of the AV include at least one of a Light Detection and Ranging (LiDAR) sensor, a Radio Detection and Ranging (RADAR), a camera, an inertial measurement unit (IMU), and a Time-of-Flight camera.

Aspect 15. The method of any of Aspects 9 to 14, wherein the difference is based on an intensity value measured by a Light Detection and Ranging (LiDAR) sensor.

Aspect 16. A non-transitory computer-readable medium having stored thereon instructions which, when executed by one or more processors, cause the one or more processors to: receive simulation data descriptive of one or more assets, wherein the one or more assets are synthetic representations of an object in a simulation scene; receive sensor data collected by one or more sensors of an autonomous vehicle (AV) while navigating in a real-world environment; identify an object in the sensor data using a machine learning model, the object corresponding to an asset of the one or more assets in the simulation data; determine a difference between the asset in the simulation data and the object in the sensor data; and based on the difference between the asset in the simulation data and the object in the sensor data, determine whether to modify at least one of the assets in the simulation scene and one or more synthetic sensors.

Aspect 17. The non-transitory computer-readable medium of Aspect 16, wherein the difference is attributed to a property of the object, the property comprising at least one of a geometry, a color, and a material of the object.

Aspect 18. The non-transitory computer-readable medium of Aspect 17, wherein determining whether to modify at least one of the asset in the simulation scene and one or more synthetic sensors includes modifying the asset in the simulation scene to emulate the property of the object that is attributed to the difference.

Aspect 19. The non-transitory computer-readable medium of any of Aspects 16 to 18, wherein the difference is attributed to one or more synthetic sensors that are used to capture the simulation data in the simulation scene.

Aspect 20. The non-transitory computer-readable medium of Aspect 19, wherein determining whether to modify at least one of the asset in the simulation scene and one or more synthetic sensors includes updating the one or more synthetic sensors to emulate the one or more sensors of the AV that are used to capture the sensor data.

Aspect 21. A system comprising means for performing a method according to any of Aspects 9 to 15.

Aspect 22. A computer-program product comprising instructions which, when executed by one or more processors, cause the one or more processors to perform a method according to any of Aspects 9 to 15.

Aspect 23. An autonomous vehicle comprising a computing device having stored thereon instructions which, when executed by the computing device, cause the computing device to perform a method according to any of Aspects 9 to 15.

What is claimed is:

1. A system comprising:
a memory; and
one or more processors coupled to the memory, the one or more processors being configured to:
receive simulation data descriptive of one or more assets, wherein the one or more assets are synthetic representations of an object in a simulation scene;
receive sensor data collected by one or more sensors of an autonomous vehicle (AV) while navigating in a real-world environment;
identify an object in the sensor data using a machine learning model, the object corresponding to an asset of the one or more assets in the simulation data;
determine a difference between the asset in the simulation data and the object in the sensor data; and
based on the difference between the asset in the simulation data and the object in the sensor data, determine whether to modify at least one of the assets in the simulation scene and one or more synthetic sensors.

2. The system of claim 1, wherein the difference is attributed to a property of the object, the property comprising at least one of a geometry, a color, and a material of the object.

3. The system of claim 2, wherein determining whether to modify at least one of the assets in the simulation scene and one or more synthetic sensors includes modifying the asset in the simulation scene to emulate the property of the object that is attributed to the difference.

4. The system of claim 1, wherein the difference is attributed to one or more synthetic sensors that are used to capture the simulation data in the simulation scene.

5. The system of claim 4, wherein determining whether to modify at least one of the asset in the simulation scene and one or more synthetic sensors includes updating the one or more synthetic sensors to emulate the one or more sensors of the AV that are used to capture the sensor data.

6. The system of claim 1, wherein the one or more sensors of the AV include at least one of a Light Detection and Ranging (LiDAR) sensor, a Radio Detection and Ranging (RADAR), a camera, an inertial measurement unit (IMU), and a Time-of-Flight camera.

7. The system of claim 1, wherein the difference is based on an intensity value measured by a Light Detection and Ranging (LiDAR) sensor.

8. The system of claim 1, wherein determining whether to modify at least one of the asset in the simulation scene and one or more synthetic sensors includes determining a degree of the difference between the asset in the simulation data and the object in the sensor data using a neural network.

9. A method comprising:
receiving simulation data descriptive of one or more assets, wherein the one or more assets are synthetic representations of an object in a simulation scene;
receiving sensor data collected by one or more sensors of an autonomous vehicle (AV) while navigating in a real-world environment;
identifying an object in the sensor data using a machine learning model, the object corresponding to an asset of the one or more assets in the simulation data;
determining a difference between the asset in the simulation data and the object in the sensor data; and
based on the difference between the asset in the simulation data and the object in the sensor data, determining whether to modify at least one of the assets in the simulation scene and one or more synthetic sensors.

10. The method of claim 9, wherein the difference is attributed to a property of the object, the property comprising at least one of a geometry, a color, and a material of the object.

11. The method of claim 10, wherein determining whether to modify at least one of the assets in the simulation scene and one or more synthetic sensors includes modifying the asset in the simulation scene to emulate the property of the object that is attributed to the difference.

12. The method of claim 9, wherein the difference is attributed to one or more synthetic sensors that are used to capture the simulation data in the simulation scene.

13. The method of claim 12, wherein determining whether to modify at least one of the assets in the simulation scene and one or more synthetic sensors includes updating the one or more synthetic sensors to emulate the one or more sensors of the AV that are used to capture the sensor data.

14. The method of claim 9, wherein the one or more sensors of the AV include at least one of a Light Detection and Ranging (LiDAR) sensor, a Radio Detection and Ranging (RADAR), a camera, an inertial measurement unit (IMU), and a Time-of-Flight camera.

15. The method of claim 9, wherein the difference is based on an intensity value measured by a Light Detection and Ranging (LiDAR) sensor.

16. A non-transitory computer-readable medium having stored thereon instructions which, when executed by one or more processors, cause the one or more processors to:
receive simulation data descriptive of one or more assets, wherein the one or more assets are synthetic representations of an object in a simulation scene;
receive sensor data collected by one or more sensors of an autonomous vehicle (AV) while navigating in a real-world environment;
identify an object in the sensor data using a machine learning model, the object corresponding to an asset of the one or more assets in the simulation data;
determine a difference between the asset in the simulation data and the object in the sensor data; and
based on the difference between the asset in the simulation data and the object in the sensor data, determine whether to modify at least one of the assets in the simulation scene and one or more synthetic sensors.

17. The non-transitory computer-readable medium of claim 16, wherein the difference is attributed to a property of the object, the property comprising at least one of a geometry, a color, and a material of the object.

18. The non-transitory computer-readable medium of claim 17, wherein determining whether to modify at least one of the asset in the simulation scene and one or more synthetic sensors includes modifying the asset in the simulation scene to emulate the property of the object that is attributed to the difference.

19. The non-transitory computer-readable medium of claim 16, wherein the difference is attributed to one or more synthetic sensors that are used to capture the simulation data in the simulation scene.

20. The non-transitory computer-readable medium of claim 19, wherein determining whether to modify at least one of the asset in the simulation scene and one or more synthetic sensors includes updating the one or more synthetic sensors to emulate the one or more sensors of the AV that are used to capture the sensor data.
